(19) United States
(12) Patent Application Publication
(10) Pub. No.: US 2024/0404963 A1
(43) Pub. Date: Dec. 5, 2024

(54) SYSTEMS, APPARATUSES, AND METHODS FOR BACK-TO-BACK DIE FOR SEMICONDUCTOR PACKAGES

(71) Applicant: STMicroelectronics International N.V., Geneva (CH)

(72) Inventor: Jean-Michel RIVIERE, Froges (FR)

(21) Appl. No.: 18/204,092

(22) Filed: May 31, 2023

(51) Int. Cl. H01L 23/00; H01L 23/36; H01L 23/498

(52) U.S. Cl. CPC H01L 23/573; H01L 23/36; H01L 23/49838; H01L 24/32; H01L 24/83; H01L 2224/32145; H01L 2224/83

(57) ABSTRACT

Systems, apparatuses, and methods for back-to-back (BTB) die for semiconductor packages are provided. For example, a semiconductor package may include a BTB die electrically coupled to a plurality of a Si blocks that may be positioned laterally from the BTB die. The semiconductor package may include a heat sink that is also electrically coupled to a plurality of Si blocks that may be positioned laterally from the BTB die. The Si blocks may be electrically coupled to terminals on a side of the semiconductor package. The Si blocks may provide for improved protection, thermal managements, and shielding.

### TECHNOLOGICAL FIELD

Example embodiments of the present disclosure relate generally to semiconductor packages, particularly to semiconductor packages with back-to-back die with panel level package (PLP).

### BACKGROUND

Semiconductor packages may be subject to probing or intrusion, particularly within certain industries that may use semiconductor packages for authentication. For example, attacks that probe or intrude on a semiconductor die may be prevalent in certain industries such as ink cartridges that use authentication chips. If successful, such attacks may allow for an attacker to learn information on a semiconductor to copy for use in counterfeit products. While the front-side or top-side of a die in a semiconductor package may have some anti-probing measures, the other sides or areas of the die in the semiconductor package may remain more exposed to probing or intrusion.

New semiconductor packages are needed. The inventors have identified numerous areas of improvement in the existing technologies and processes, which are the subjects of embodiments described herein. Through applied effort, ingenuity, and innovation, many of these deficiencies, challenges, and problems have been solved by developing solutions that are included in embodiments of the present disclosure, some examples of which are described in detail herein.

### BRIEF SUMMARY

Various embodiments described herein relate to systems, apparatuses, and methods for back-to-back (BTB) die for semiconductor packages.

In accordance with some embodiments of the present disclosure, an example semiconductor package is provided. The semiconductor package may comprise: a first side of the semiconductor package and a second side of the semiconductor package, wherein the second side of the semiconductor package includes a plurality of terminals; a back-to-back (BTB) die comprised of a first die electrically coupled to a second die; the first die electrically coupled to a first portion of the plurality of terminals through a first plurality of electrical traces and a plurality of Si blocks; the second die electrically coupled to a second portion of the plurality of terminals through a second plurality of electrical traces; wherein the BTB die is configured to cease functioning if an electrical connection to one of the plurality of terminals is broken.

In some embodiments, the semiconductor package comprises a heat sink on the first side of the semiconductor package.

In some embodiments, the heat sink is coupled to one or more terminals on the second side of the semiconductor package by one or more Si blocks.

In some embodiments, the first die is electrically coupled to the first plurality of traces with a plurality of vias through a first lamination layer.

In some embodiments, the first lamination layer is comprised of ABF.

In some embodiments, at least one of the plurality of Si blocks is positioned on at least a first lateral side of the BTB die and at least a second of the plurality of Si blocks is positioned on at least a second lateral side of the BTB die.

In some embodiments, each lateral side of the BTB die has at least one of the plurality of Si blocks are positioned on the respective lateral side.

In some embodiments, a first Si block of the plurality of Si blocks is a different height than at least a second Si block of the plurality of Si blocks.

In some embodiments, the plurality of electrical traces are in a fan-out pattern.

In some embodiments, the semiconductor package is a first semiconductor package in a plurality of semiconductor packages in a panel.

In accordance with some embodiments of the present disclosure, an example method of manufacturing is provided. The method of manufacturing may comprise: preparing a back-to-back (BTB) die comprising of a first die electrically coupled to a second die; forming a first side of the semiconductor package and a second side of the semiconductor package including electrically coupling a plurality of Si blocks to the first die via a plurality of traces and electrically coupling a plurality of terminals on the second side of the semiconductor package to the second die; wherein the BTB die is configured to cease functioning if an electrical connection to one of the plurality of terminals is broken.

In some embodiments, forming a first side of the semiconductor package and a second side of the semiconductor package further includes forming a heat sink on the first side of the semiconductor package.

In some embodiments, forming a first side of the semiconductor package and a second side of the semiconductor package further includes forming the heat sink on the first side of the semiconductor package to be electrically coupled to one or more of the plurality of Si blocks.

In some embodiments, forming a first side of the semiconductor package and a second side of the semiconductor package further includes electrically coupling the plurality of traces to the first die with a plurality of vias through a first lamination layer.

In some embodiments, the first lamination layer is comprised of ABF.

In some embodiments, at least one of the plurality of Si blocks is positioned on at least a first lateral side of the BTB die and at least a second of the plurality of Si blocks is positioned on at least a second lateral side of the BTB die.

In some embodiments, each lateral side of the BTB die has at least one of the plurality of Si blocks are positioned on the respective lateral side.

In some embodiments, a first Si block of the plurality of Si blocks is a different height than at least a second Si block of the plurality of Si blocks.

In some embodiments, the plurality of electrical traces are in a fan-out pattern.

In some embodiments, the semiconductor package is a first semiconductor package in a plurality of semiconductor packages in a panel.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF SUMMARY OF THE DRAWINGS

Having thus described certain example embodiments of the present disclosure in general terms, reference will now be made to the accompanying drawings, which are not necessarily drawn to scale, and wherein:

FIG. 1 illustrates a cross-section view of a block diagram of a first semiconductor package with a BTB die in accordance with one or more embodiments of the present disclosure;

FIG. 2A illustrates a cross-section view of a block diagram of a second semiconductor package with a BTB die in accordance with one or more embodiments of the present disclosure;

FIG. 2B illustrates a cross-section view of a block diagram of a third semiconductor package with a BTB die in accordance with one or more embodiments of the present disclosure;

FIG. 3 illustrates a top-view of a cross section of a semiconductor package with a BTB die in accordance with one or more embodiments of the present disclosure;

FIG. 4 illustrates an example flowchart of operations for manufacturing a semiconductor package in accordance with one or more embodiments of the present disclosure;

FIG. 5 illustrates an example flowchart of operations for preparing BTB die(s) in accordance with one or more embodiments of the present disclosure;

FIG. 6A-6F illustrate example block diagrams associated with operations for preparing BTB die(s) in accordance with one or more embodiments of the present disclosure;

FIG. 7 illustrates an example flowchart of operations for forming a first side of the semiconductor package(s) in accordance with one or more embodiments of the present disclosure;

FIG. 8A-8Q illustrate cross-section views of example block diagrams associated with operations for forming a first side of the semiconductor package(s) in accordance with one or more embodiments of the present disclosure;

FIGS. 9A-9B illustrate an example flowchart of operations for forming a second side of the semiconductor package(s) in accordance with one or more embodiments of the present disclosure;

FIGS. 10A-10Y illustrate cross-section views of example block diagrams associated with operations for forming a second side of the semiconductor package(s) in accordance with one or more embodiments of the present disclosure; and

FIG. 11 illustrates an example flowchart of operations for finishing semiconductor package(s) in accordance with one or more embodiments of the present disclosure.

### DETAILED DESCRIPTION

Some embodiments of the present disclosure will now be described more fully herein with reference to the accompanying drawings, in which some, but not all, embodiments of the disclosure are shown. Indeed, various embodiments of the disclosure may be embodied in many different forms and should not be construed as limited to the embodiments set forth herein; rather, these embodiments are provided so that this disclosure will satisfy applicable legal requirements. Like reference numerals refer to like elements throughout.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in various embodiments,” “in one embodiment,” “according to one embodiment,” “in some embodiments,” and the like generally mean that the particular feature, structure, or characteristic following the phrase may be included in at least one embodiment of the present disclosure and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments or it may be excluded.

The use of the term “circuitry” as used herein with respect to components of a system or an apparatus should be understood to include particular hardware configured to perform the functions associated with the particular circuitry as described herein. The term “circuitry” should be understood broadly to include hardware and, in some embodiments, software for configuring the hardware. For example, in some embodiments, “circuitry” may include processing circuitry, communications circuitry, input/output circuitry, and the like. In some embodiments, other elements may provide or supplement the functionality of particular circuitry.

### Overview

Various embodiments of the present disclosure are directed to improved semiconductor packages, particularly back-to-back (BTB) die for semiconductor packages. Various embodiments of semiconductor packages with BTB die include Si blocks for improved protection, thermal dissipation, and/or shielding.

Semiconductor packages may be subject to intrusion attacks to try and copy the information on one or more dice. For example, semiconductor packages in ink cartridges for printers may include one or more dice used for authentication of the ink cartridge. Attackers may try and attack the semiconductor packages to access a die and to copy the ability to authenticate an ink cartridge. A top side or front-side of the semiconductor package may include a heat sink or metal layer to not only provide heat dissipation but as well to provide an anti-probing measure. Additional measures are taken by embodiments described herein.

For example, the lateral sides of the semiconductor package described herein may be provided with anti-probing measures of Si blocks that would be damaged or destroyed during an intrusion attack. A BTB die may be configured so that if an intrusion attack were to damage, destroy, break, etc. one of the Si blocks or other electrical couplings to one of a plurality of terminals then the BTB die would cease to function. Thus an attack or probe would be thwarted. Additionally or alternatively, the Si blocks may provide improved thermal management with the dissipation of heat through Si blocks connected to a heat sink. Further, the Si blocks may provide for improved EMI shielding for the semiconductor package.

In various embodiments the semiconductor package of the present disclosure may be manufactured in panel level packaging (PLP) with a plurality of similar and/or different semiconductor packages.

It should be readily appreciated that the embodiments described herein may be configured in various additional and alternative manners in addition to those expressly described herein.

### Exemplary Systems and Apparatuses

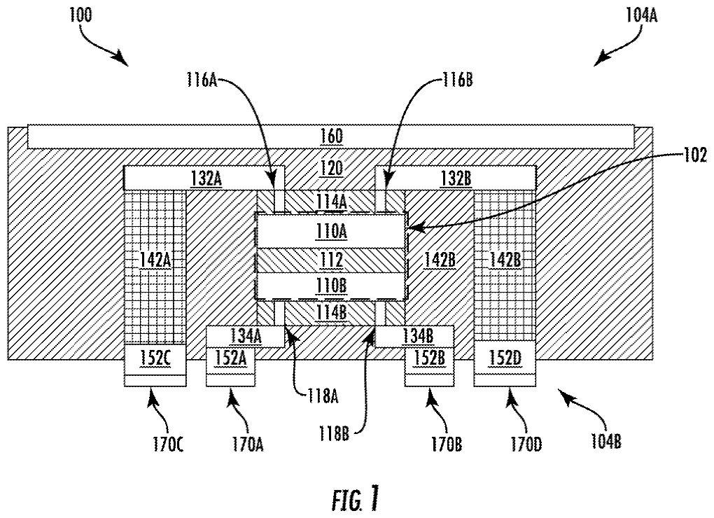

Embodiments of the present disclosure described herein include systems and apparatuses for back-to-back (BTB) die for semiconductor packages that may be implemented in various embodiments. FIGS. 1, 2A, 2B, and 3 illustrate embodiments of a semiconductor package including a BTB die. The BTB die 102 is comprised of a first die 110A coupled to a second die 110B through a BTB connecting layer 112 (e.g., tape, glue, ABF, or the like). There may be a plurality of electrical connections that electrically couple the first die 110A to the second die 110B through the BTB connecting layer 112. The semiconductor package may have a first side (i.e., top side as illustrated) and a second side (i.e., bottom side as illustrated).

FIG. 1 illustrates a cross-section view of a block diagram of a first semiconductor package with a BTB die in accordance with one or more embodiments of the present disclosure.

Semiconductor package 100 of FIG. 1 includes a BTB die 102. Each side of the BTB die 102 may have applied to it a BTB film layer 114. For example, a first side 104A of the BTB die 102 may have an first side BTB film layer 114A and a second side 104B of the BTB die 102 may have a second side BTB film layer 114B. A plurality of vias 116 through the first side BTB film layer 114A may connect a first plurality of traces 132 to the first die 110A of the BTB die 102. A plurality of vias 118 through the second side BTB film layer 114B may connect a second plurality of traces 134 to the second die 110B of the BTB die 102.

The first plurality of traces 132 may each be electrically coupled to an associated Si block 142. Each Si block 142 may be electrically coupled to a stud 152, which is electrically coupled to a terminal 170. For example, trace 132A is electrically coupled to the first die 110A through via 116A and to Si block 142A, which is electrically coupled to stud 152C, which is electrically coupled to terminal 170C. Also, trace 132B is electrically coupled to the first die 110A through via 116B and to Si block 142B, which is electrically coupled to stud 152D, which is electrically coupled to terminal 170D. The vias 116, 118 may be of one or more shapes.

The second plurality of traces 134 may each be electrically coupled to a stud 152, which is electrically coupled to a terminal 170. For example, trace 134A is electrically coupled to the second die 110B through via 118A and to stud 152A, which is electrically coupled to terminal 170A. Also, trace 134B is electrically coupled to the second die 110B through via 118B and to stud 152B, which is electrically coupled to terminal 170B.

While FIG. 1 is a cross-section view of an example semiconductor package 100 that illustrates four terminals 170 and four Si blocks 142, it will be readily appreciated that additional terminals 170 may be electrically coupled through Si blocks 142 to the first wafer 110A in a similar manner. Also, it will be readily appreciated that additional terminals 170 may be electrically coupled through traces 134 to the second die 110A in a similar manner. The semiconductor package 100 may be electrically connected to a larger system or apparatus via the terminals 170.

A molding 120 encases the BTB die 102 and its electrical connections to the terminals 170.

Semiconductor package 100 includes a heat sink 160 on the first side 104A. The heat sink 160 may provide intrusion protection from the top. The sides of the semiconductor package 100 are protected from intrusion attacks with the molding and the Si blocks. If the traces 132, 134 or the Si blocks 142 are broken or disturbed, the BTB die 102 will cease to function. The heat sink 160 also provides from thermal dissipation as well as EMI shielding.

In various embodiments, the film for the BTB connecting layer 112, the first side BTB film layer 114A, and the second side BTB film layer 114B may be the same material (e.g., ABF or the like). Alternatively, the film for one or more of the BTB connecting layer 112, the first side BTB film layer 114A, and the second side BTB film layer 114B may be different materials.

In various embodiments, the studs 152 may be arranged in a fan-out pattern where studs 152 and traces 132, 134 connecting to the studs may be routed outwards and/or inwards beyond a lateral side of the BTB die 102.

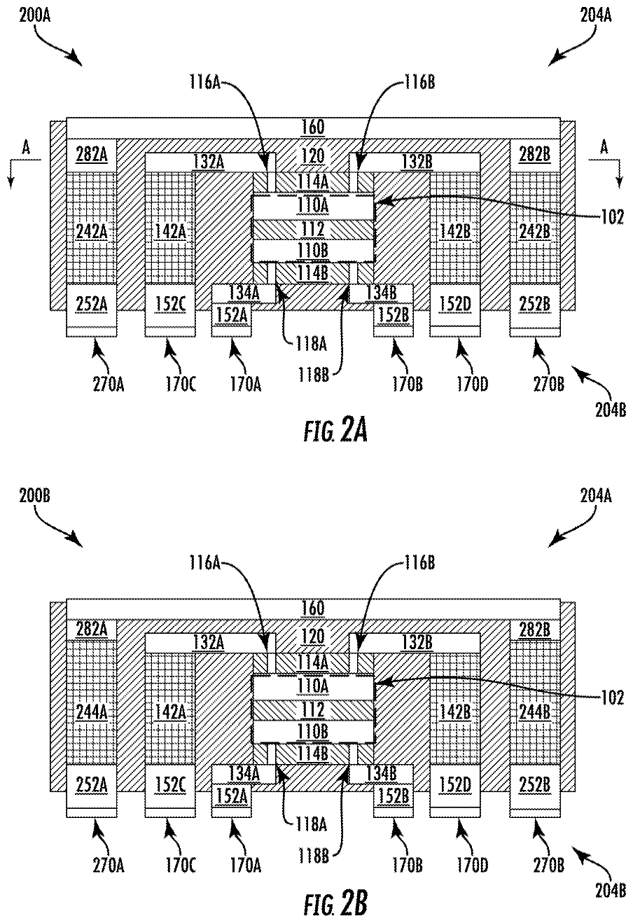

FIG. 2A illustrates a cross-section view of a block diagram of a second semiconductor package with a BTB die in accordance with one or more embodiments of the present disclosure. The semiconductor package 200A of FIG. 2A is similar to the semiconductor package of FIG. 1 with semiconductor package 200A further including Si blocks 242A, 242A that electrically couple the heat sink 160 to terminals 270A, 270B through, respectively, studs 282A, 282B and studs 252A, 252B.

The electrical coupling of the heat sink 160 to the terminals 270A, 270B provides, for example, for additional protection from intrusion attacks. It also provides for improved thermal management by creating paths for heat to be transmitted and/or dissipate. Additionally, it provides for improved shielding for the semiconductor package by providing additional electromagnetic interference (EMI) protection.

FIG. 2A also illustrates a layer A, which is a cross-section of the example embodiment in FIG. 2A that is used in association with FIG. 3.

FIG. 2B illustrates a cross-section view of a block diagram of a third semiconductor package with a BTB die in accordance with one or more embodiments of the present disclosure. The semiconductor package 200B illustrated in FIG. 2B is similar to the semiconductor package illustrated in FIG. 2A. However, semiconductor package 200B includes Si blocks 244A, 244B that have a different height from the height of the Si blocks 142A, 142B. As illustrated, the Si blocks 244A, 244B may have a height greater than the Si blocks 142A, 142B. Alternatively, the Si blocks 244A, 244B may have a height that is less than the height of Si blocks 142A, 142B.

In various embodiments, the height of the Si blocks (e.g., 242 or 244) coupling a heat sink 160 with a stud 252 (e.g., 252A, 252B) may be the same or different height than Si blocks (e.g., 142) coupling a BTB die with studs (e.g., 152C, 152D) and also may be offset in a direction of the height. The offset may, for example, provide coverage for one or more portions of the semiconductor package that might otherwise be exposed to an attacker's probe.

As will be appreciated, various of the semiconductor packages 100, 200A, 200B described herein do not include bumping or wire bonding internal to the semiconductor package, which may increase manufacturing steps. Thus various embodiments described herein provide for increased manufacturability in addition to improved intrusion protection, thermal management, and shielding.

FIG. 3 illustrates a top-view of a cross section of a semiconductor package with a BTB die in accordance with one or more embodiments of the present disclosure. The top-view cross section is taken along a plane indicated with A in FIG. 2A. The cross-section of FIG. 3 omits molding 120 which would otherwise be present in semiconductor package 200A.

As illustrated in the top-view, the semiconductor package 200A may include a plurality of traces 132A-132F. Each of the plurality of traces 132 may be electrically coupled to one or more of a plurality of input/output and/or signal pads on a die (e.g., 110A) and also electrically coupled to a corresponding Si block 142A-142F. There are also additional Si blocks 282A-F that may be electrically coupled a heat sink 160 to terminals of the semiconductor package 200A.

While FIG. 3 illustrates traces 132A-132F on two lateral sides of the BTB die 102 under first side BTB film layer 114A, it will be appreciated that the traces 132 may be provided in additional directions or fewer directions. This may have traces 132 and associated Si blocks 142 on each side of a BTB die 102. For example, there may be six input/output pads that are electrically coupled to traces 132A-132E. Additionally or alternatively, the Si blocks 282 electrically coupling the heat sink 160 to terminals 170 may also be located in various locations in the semiconductor package 200A. For example, Si blocks 282 may be located on lateral sides of the semiconductor package and/or around the perimeter of the semiconductor package 200A to, among other things, prevent intrusion attacks from associated sides of the semiconductor package 200A.

It should be readily appreciated that the embodiments of the systems and apparatuses, described herein may be configured in various additional and alternative manners in addition to those expressly described herein.

### Exemplary Methods

Embodiments of the present disclosure include methods for manufacturing various embodiments of the back-to-back (BTB) die semiconductor packages described herein.

In various embodiments, semiconductor packages described herein may be manufactured alone as with a plurality of additional semiconductor packages, such as on a panel with panel-level packaging (PLP). It will be appreciated that while operations described herein may refer to a panel, the operations may be performed on a panel, a wafer, or the like.

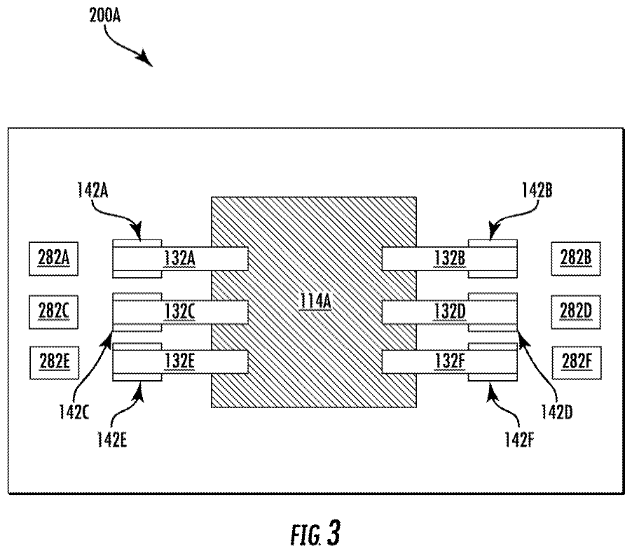

FIG. 4 illustrates an example flowchart of operations for manufacturing a semiconductor package in accordance with one or more embodiments of the present disclosure.

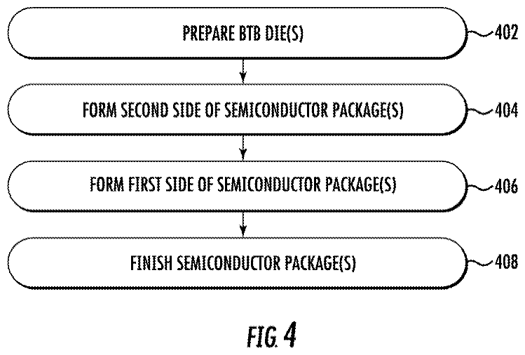

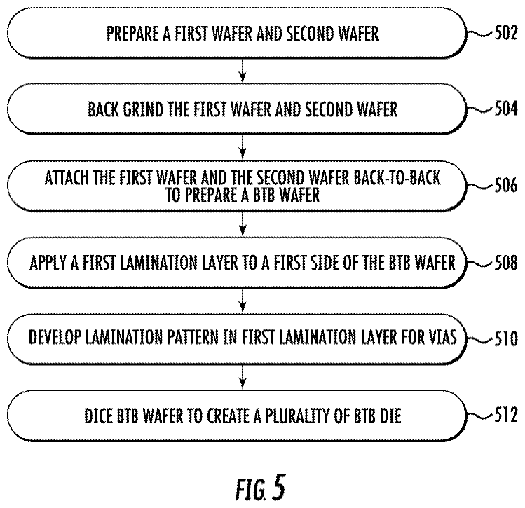

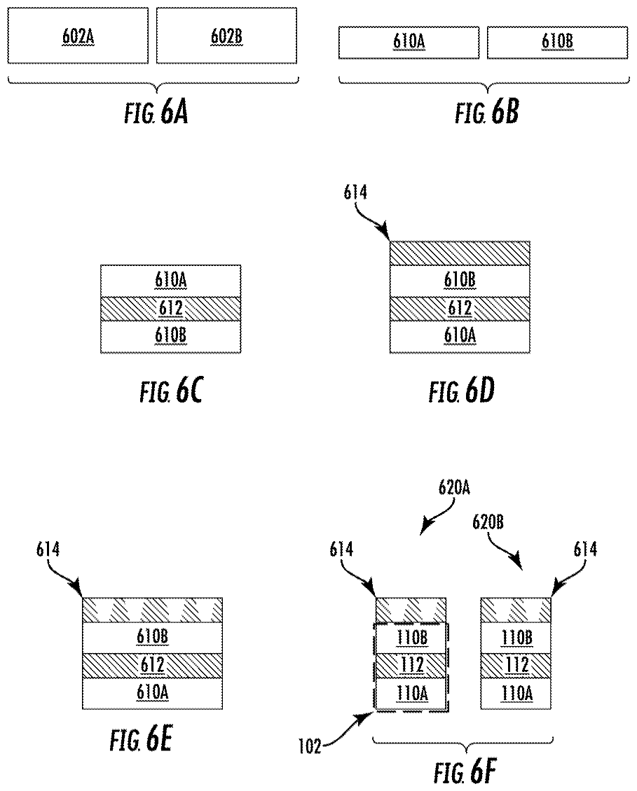

At operation 402, prepare BTB die(s). One or more BTB dies may be prepared at the same time. Alternatively, a single BTB die 102 may be prepared. Additional operations associated with operation 402 are described herein in relation to FIGS. 5 and 6.

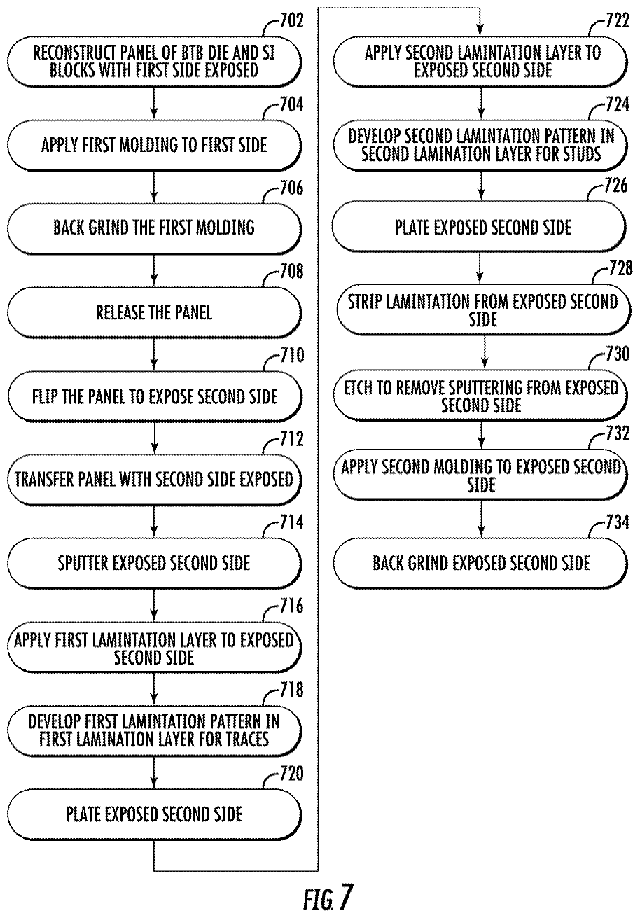

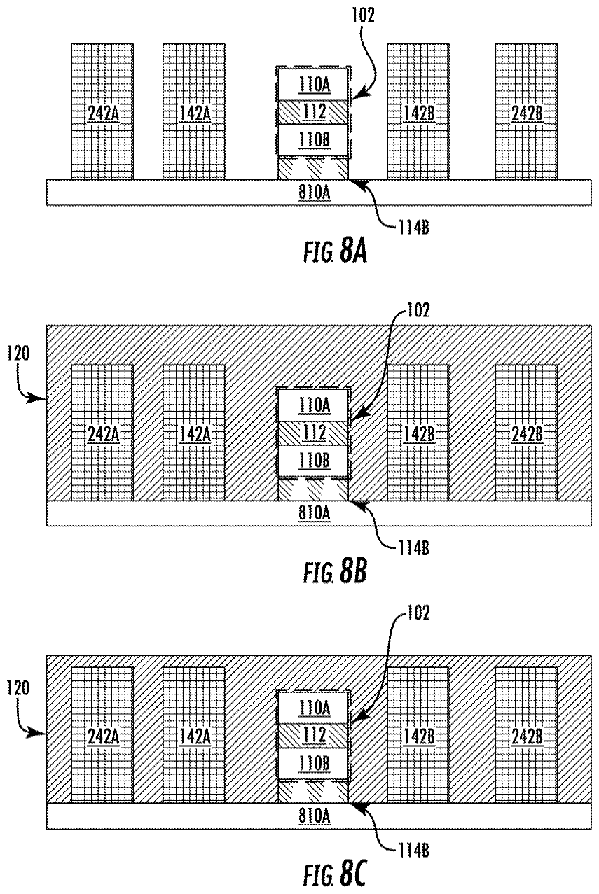

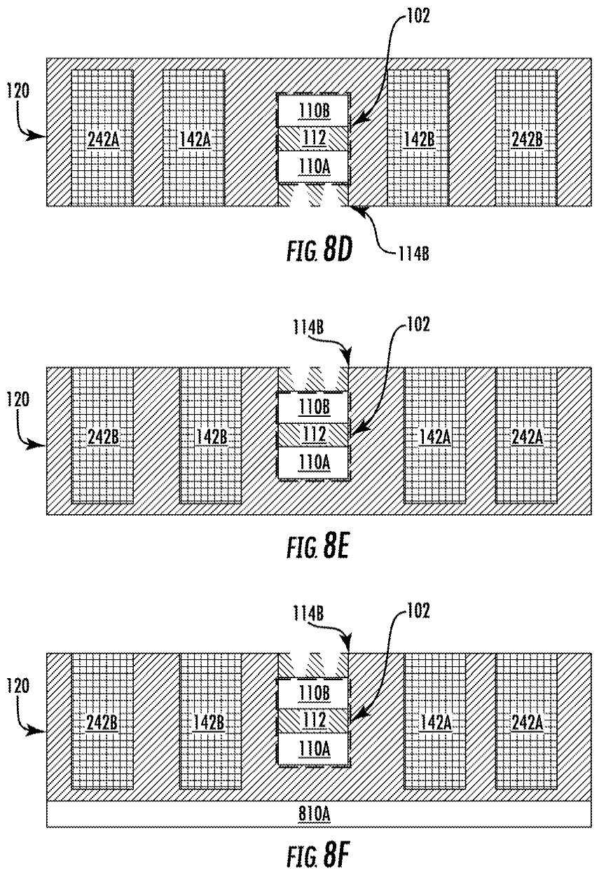

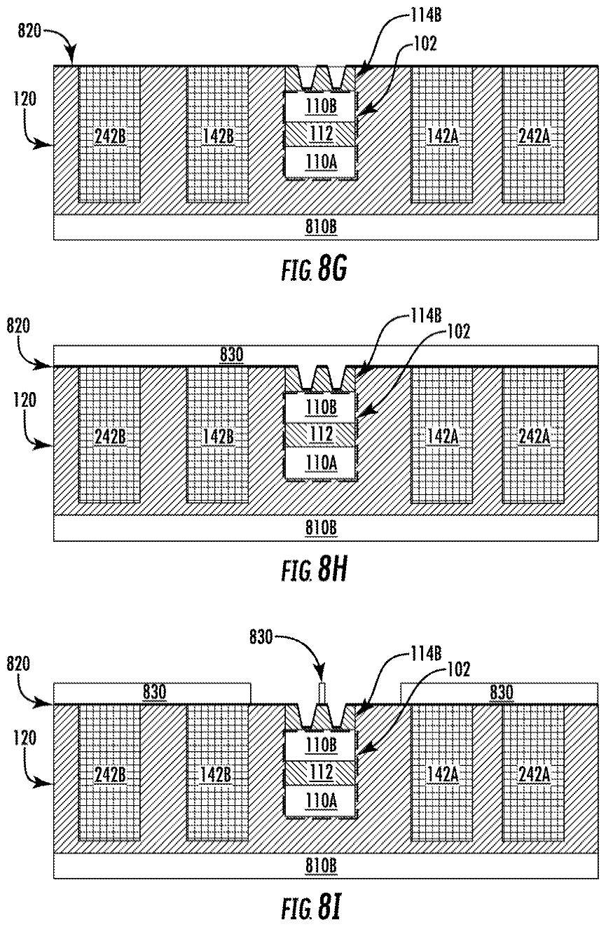

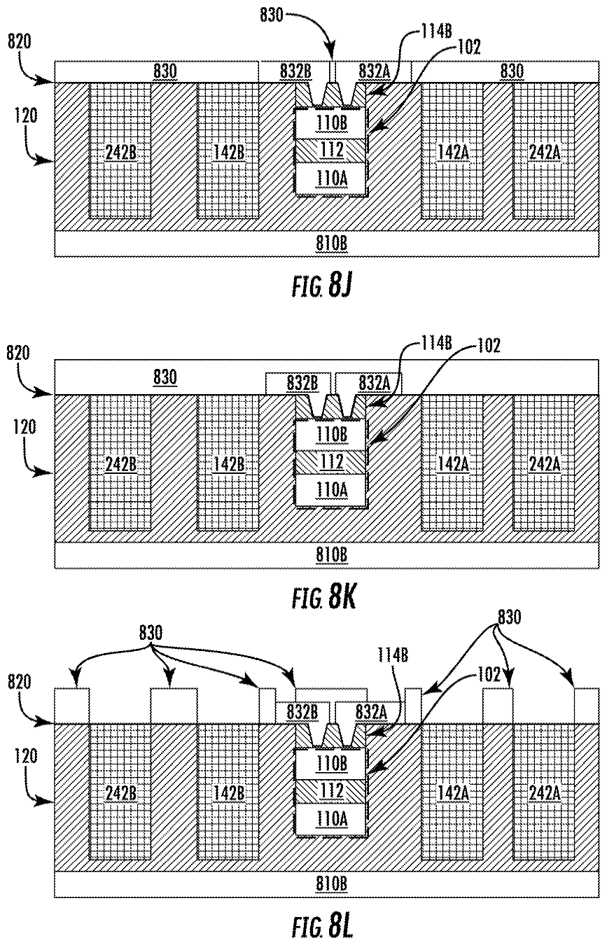

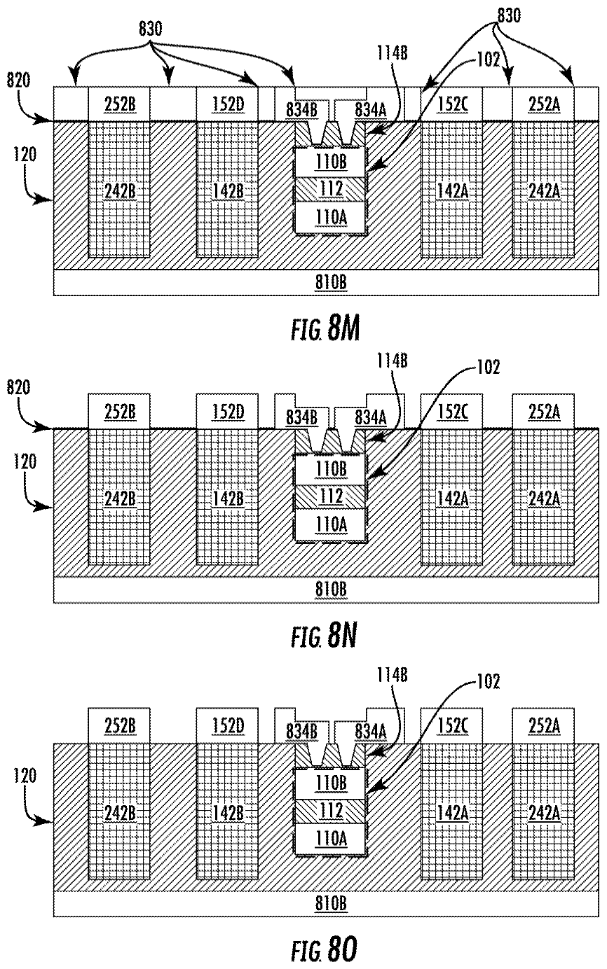

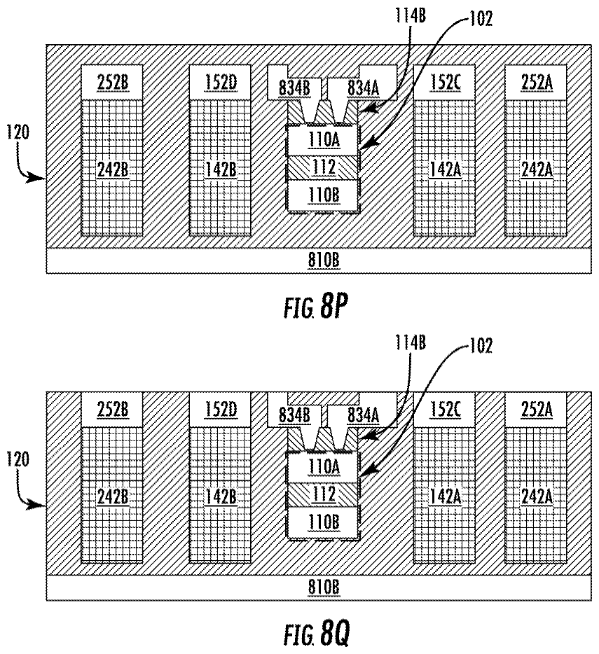

At operation 404, form second side of semiconductor package. Additional operations associated with operation 404 are described herein in relation to FIGS. 7 and 8A-8Q.

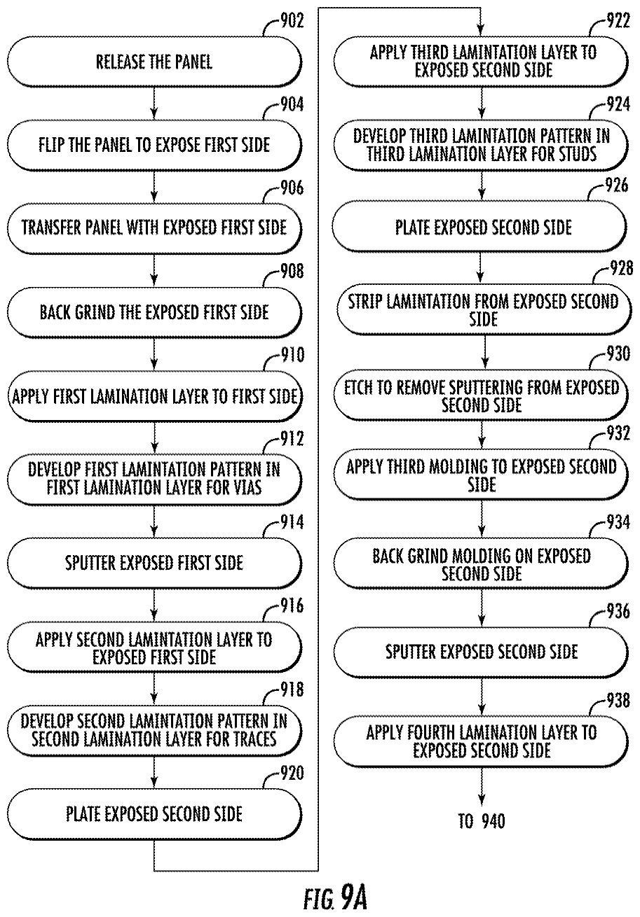

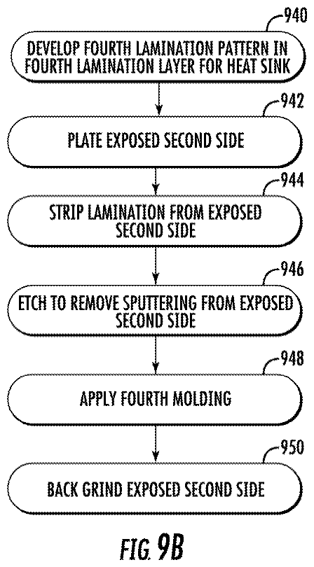

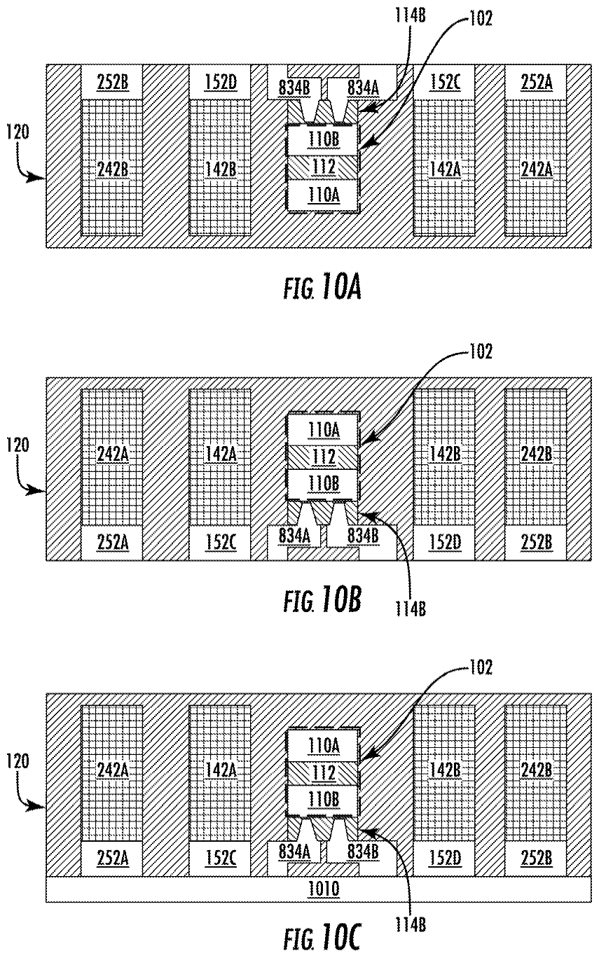

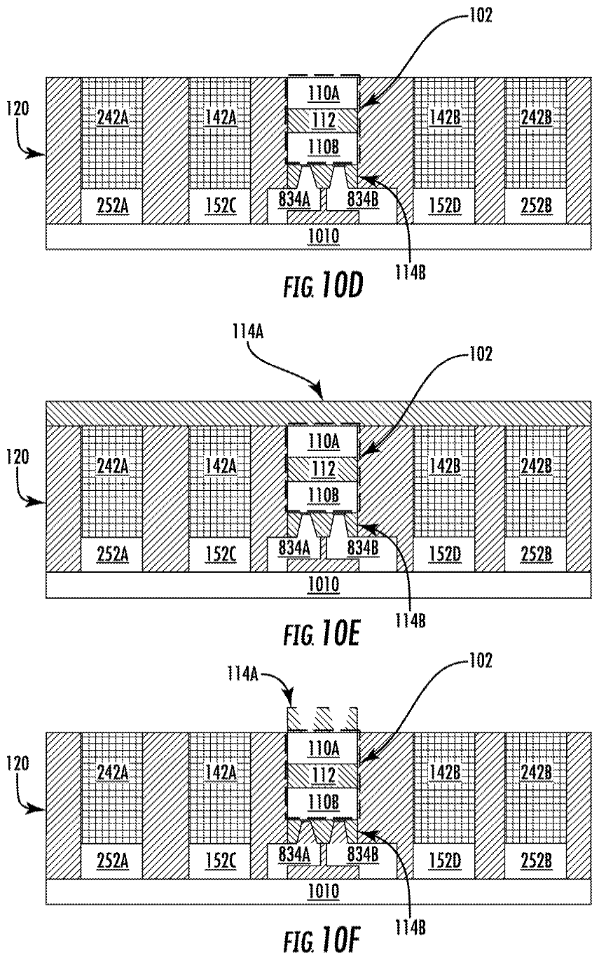

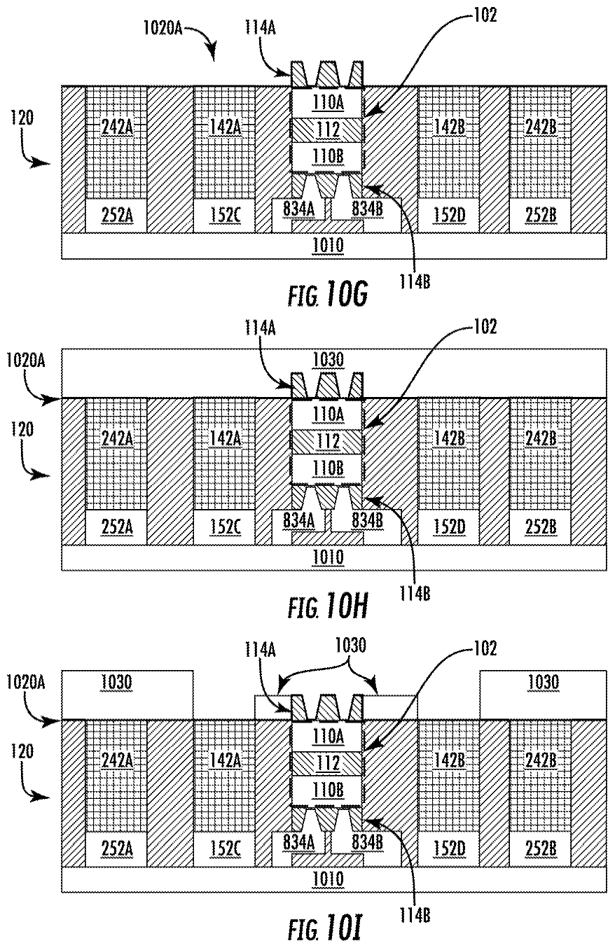

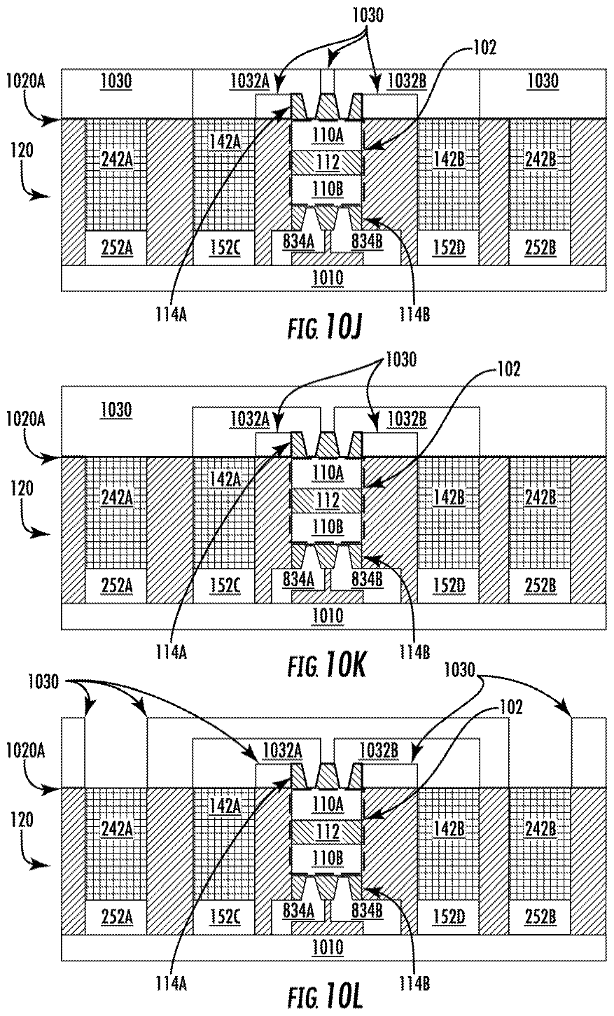

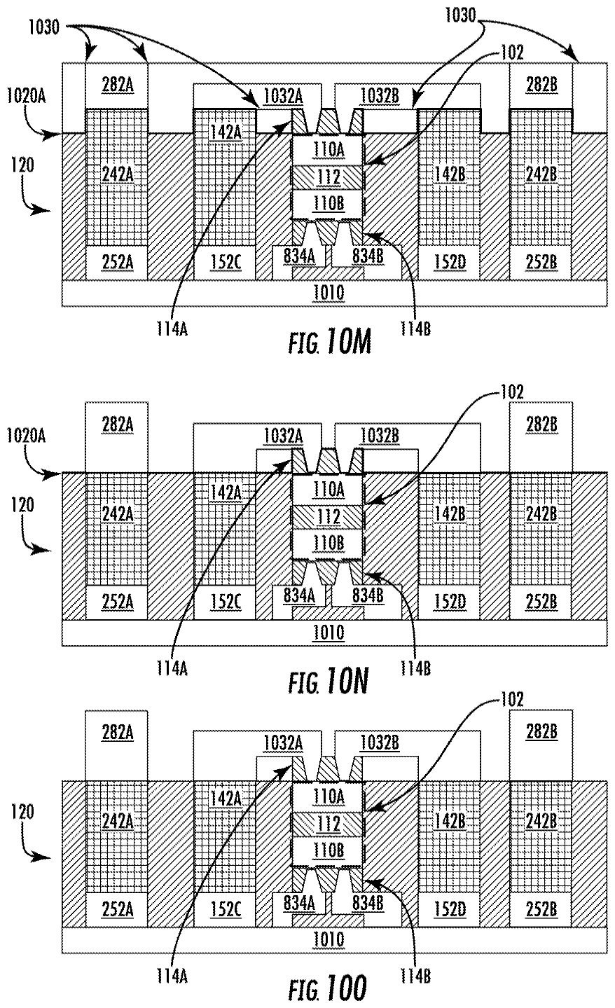

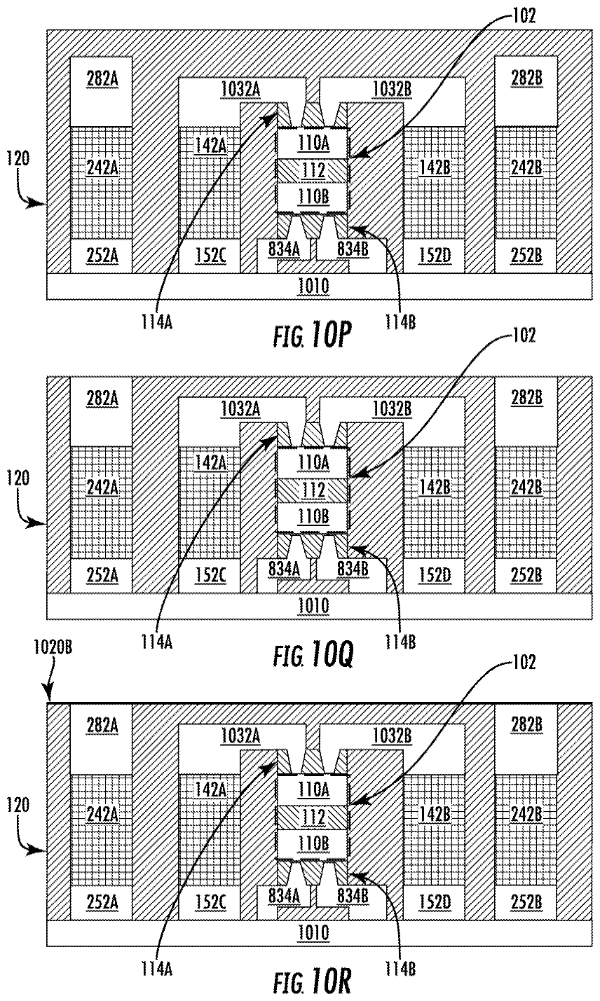

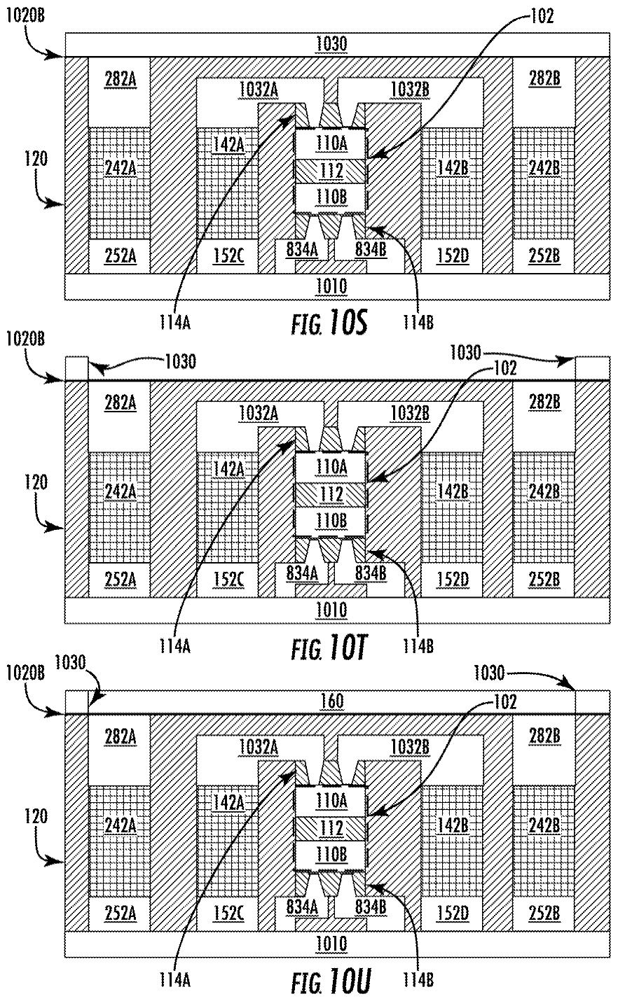

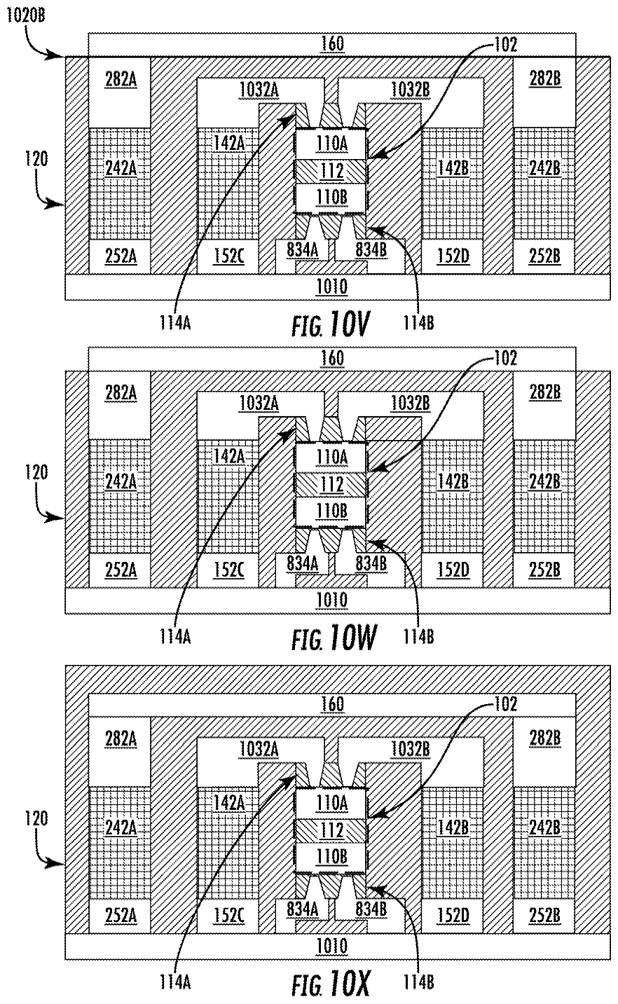

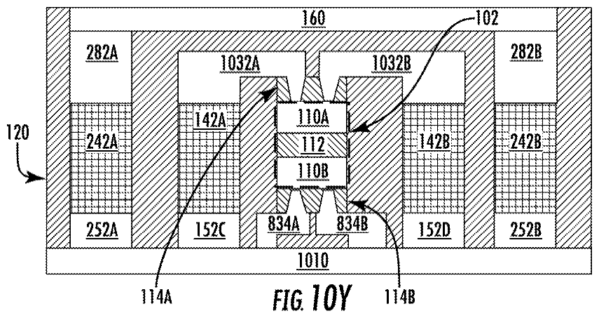

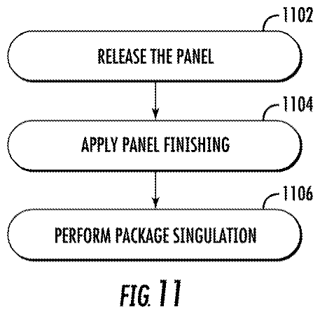

At operation 406, form first side of semiconductor package. Additional operations associated with operation 406 are described herein in relation to FIGS. 9A, 9B, and 10A-10X.

At operation 408, finish (or complete) semiconductor package. Additional operations associated with operation 402 are described herein in relation to FIG. 11.

FIG. 5 illustrates an example flowchart of operations for preparing BTB die(s) in accordance with one or more embodiments of the present disclosure.

At operation 502, prepare a first wafer and a second wafer. The first wafer 602A and the second wafer 602B may each contain a plurality of dies. An illustration of an example embodiment after this operation has been performed is in FIG. 6A.

At operation 504, back grind the first wafer and the second wafer. The first wafer 602A and the second wafer 602B may respectively have back grinding performed to have a first height that will be used for the BTB die. Thus the background first wafer 610A and background second wafer 610B may be prepared for forming a BTB die. An illustration of an example embodiment after this operation has been performed is in FIG. 6B.

At operation 506, attach the first wafer and the second wafer back-to-back to prepare a BTB wafer. The BTB wafer is comprised a plurality of BTB die. The first wafer 610A and the second wafer 610B may be attached by a BTB connecting layer 612 to form a BTB wafer. The BTB connecting layer 612 may be comprised of die attach film, glue, a plurality of direct bonds, etc. An illustration of an example embodiment after this operation has been performed is in FIG. 6C.

At operation 508, apply a first lamination layer to a first side of the BTB wafer. The first lamination layer 614 may be comprised of, for example, ABF or the like. An illustration of an example embodiment after this operation has been performed is in FIG. 6D.

At operation 510, develop lamination pattern in first lamination layer for vias. The lamination pattern in the first lamination layer 614 may be developed for, for example, a plurality of vias. Each BTB die of the BTB wafer may have a plurality of vias in the first lamination pattern associated with it. The lamination pattern may be created with or more operations of laser via, plasma etch, and back grinding the first lamination. An illustration of an example embodiment after this operation has been performed is in FIG. 6E.

At operation 512, dice the BTB wafer to prepare a plurality of BTB dies. The plurality of BTB die in the BTB wafer may be separated from each other by dicing or the like. The dicing may separate the BRB from each other. An illustration of an example embodiment after this operation has been performed is in FIG. 6F. FIG. 6F illustrates a first BTB die 620A and a second BTB 620B. It will be appreciated that a BTB wafer may be comprised of many more BTB die not illustrated.

FIG. 7 illustrates an example flowchart of operations for forming a first side of the semiconductor package(s) in accordance with one or more embodiments of the present disclosure. An illustration of an example embodiments after the operations of FIG. 7 have been performed are illustrated in FIGS. 8A-8Q, which illustrate cross-section views of example block diagrams associated with operations for forming a first side of the semiconductor package(s) in accordance with one or more embodiments of the present disclosure. While FIGS. 8A-8Q illustrate an embodiment similar to that of FIG. 2A, it will be appreciated that the operations described herein may also be for other embodiments of the present disclosure.

At operation 702, reconstruct panel of BTB die and Si blocks with first side exposed. As described herein, embodiments may include a plurality of Si. blocks. A BTB die and the associated Si blocks (e.g., 142, 242) are placed with a first side of the BTB die exposed. The BTB die and associated Si blocks may be attached to a carrier 810A. The attachment may be, for example, with tape lamination and/or die attach. The panel may be constructed so that a first side of the BTB die is exposed, which may be the side of the BTB die opposite from the lamination layer 114B. An illustration of an example embodiment after this operation has been performed is in FIG. 8A.

At operation 704, apply first molding to first side. The molding 120 may encase the BTB die and the Si blocks (e.g., 142, 242). An illustration of an example embodiment after this operation has been performed is in FIG. 8B.

At operation 706, back grind the first molding. The back grinding of the molding 120 may remove molding 120 to a desired height. An illustration of an example embodiment after this operation has been performed is in FIG. 8C.

At operation 708, release the panel. The panel may be released from the carrier 810A. An illustration of an example embodiment after this operation has been performed is in FIG. 8D.

At operation 710, flip the panel to expose the second side. The panel may be flipped to expose the second side of the BTB die(s) of the panel. An illustration of an example embodiment after this operation has been performed is in FIG. 8E.

At operation 712, transfer the panel with the second side exposed. The transfer of the panel may be to a second carrier 810B. The second carrier 810B may be (or may not be) the same as the first carrier 810A. Transfer to the second carrier 810B may include attachment to the second carrier 810B by, for example, tape lamination and/or die attach. An illustration of an example embodiment after this operation has been performed is in FIG. 8F.

At operation 714, sputter exposed second side. The sputtering may be with a sputtering material, such as Ti/Cu or the like. The sputtering may create a sputtering layer 820. An illustration of an example embodiment after this operation has been performed is in FIG. 8G.

At operation 716, apply first lamination layer to exposed second side. The first lamination layer of lamination 830 may cover the sputtering layer 820. The lamination may be, for example, a dry film or the like. An illustration of an example embodiment after this operation has been performed is in FIG. 8H.

At operation 718, develop first lamination pattern in first lamination layer for traces. A first lamination pattern may be developed in the first lamination layer 830 by removing one or more portions of the first lamination layer 830. For example, one or more portions of the lamination layer 830 may be removed to provide a pattern for traces, vias, and/or electrical connections to the BTB die. The first lamination layer 830 may have the pattern developed by, for example, laser direct imaging (LDI) or the like. An illustration of an example embodiment after this operation has been performed is in FIG. 8I.

At operation 720, plate exposed second side. Metal plating on the exposed second side may generate vias and/or traces. The metal plating may, for example, be copper. An illustration of an example embodiment after this operation has been performed is in FIG. 8J. The vias and traces are collectively illustrated as 832A and 832B.

At operation 722, apply second lamination layer to exposed second side. The second lamination layer may, in some areas, be applied on the first lamination layer. An illustration of an example embodiment after this operation has been performed is in FIG. 8K.

At operation 724, develop second lamination pattern in second lamination layer for studs. A second lamination pattern may be developed in the lamination 830 from the first lamination layer and the second lamination layer. The second lamination pattern may be, for example, for studs that will provide for electrical coupling of the BTB die on the second side. An illustration of an example embodiment after this operation has been performed is in FIG. 8L. In various embodiments, the lamination 830 and the lamination layers may be used to develop patterns for a fan-out semiconductor package with the electrical connections from the semiconductor package being fanned out from the BTB die.

At operation 726, plate exposed second side. Metal plating on the exposed second side may generate studs or the like. For the Si blocks the studs 152, 252 may be electrically coupled to the Si blocks. For the traces, the studs may be electrically coupled to the traces 832A, 832B, which are collectively illustrated as traces 834A, 834B. The metal plating may, for example, be copper. An illustration of an example embodiment after this operation has been performed is in FIG. 8M.

At operation 728, strip lamination from exposed second side. Stripping the lamination 830 may remove the lamination 830. For example, the lamination stripping may remove dry film lamination. An illustration of an example embodiment after this operation has been performed is in FIG. 8N.

At operation 730, etch to remove sputtering from exposed second side. The etch may remove the sputtering layer 820, such as a Ti/Cu sputtering layer or the like. An illustration of an example embodiment after this operation has been performed is in FIG. 8O.

At operation 732, apply second molding to exposed second side. The second molding may be applied to encase the second side. The second molding may (or may not) be the same as the first molding 120. An illustration of an example embodiment after this operation has been performed is in FIG. 8P.

At operation 734, back grind exposed second side. Back grinding the exposed second side may remove molding 120 to expose the external electrical connections, such as studs 152, 252 and/or traces 834. An illustration of an example embodiment after this operation has been performed is in FIG. 8Q.

FIGS. 9A-9B illustrate an example flowchart of operations for forming a second side of the semiconductor package(s) in accordance with one or more embodiments of the present disclosure. An illustration of an example embodiments after the operations of FIGS. 9A-9B have been performed are illustrated in FIGS. 10A-10Y, which illustrate cross-section views of example block diagrams associated with operations for forming a second side of the semiconductor package(s) in accordance with one or more embodiments of the present disclosure. While FIGS. 10A-10Y illustrate an embodiment similar to that of FIG. 2A, it will be appreciated that the operations described herein may also be for other embodiments of the present disclosure.

At operation 902, release the panel. The panel may be released from the carrier 810B. An illustration of an example embodiment after this operation has been performed is in FIG. 10A.

At operation 904, flip the panel to expose the first side. The panel may be flipped to expose the first side of panel, which may be associated with the first side of the BTB die(s). An illustration of an example embodiment after this operation has been performed is in FIG. 10B.

At operation 906, transfer panel with exposed first side. The transfer of the panel may be to a carrier 1010. This may be a third carrier. In various embodiments carrier may (or may not) be the same as carrier 810A and/or 810B. Transfer to the carrier 1010 may include attachment to the carrier 1010 by, for example, tape lamination and/or die attach. An illustration of an example embodiment after this operation has been performed is in FIG. 10C.

At operation 908, back grind the exposed first side. Back grinding may remove molding 120 to expose the first die 110A of the BTB die. The back grinding may also reduce the height of an Si block 142, 242. An illustration of an example embodiment after this operation has been performed is in FIG. 10D.

At operation 910, apply a first lamination layer to the first side. The first lamination layer 114A may be, for example, a film, such as ABF of the like. An illustration of an example embodiment after this operation has been performed is in FIG. 10E.

At operation 912, develop first lamination pattern in first lamination layer for vias. The first lamination pattern in the first lamination layer 114A may be developed for, for example, a plurality of vias. The BTB wafer 110A may have a plurality of vias in the first lamination pattern associated with it. The lamination pattern may be created with or more operations of laser via, plasma etch, and back grinding the first lamination layer 114A. An illustration of an example embodiment after this operation has been performed is in FIG. 10F.

At operation 914, sputter exposed first side. The sputtering may be with a sputtering material, such as Ti/Cu or the like. The sputtering may create a sputtering layer 1020A. An illustration of an example embodiment after this operation has been performed is in FIG. 10G.

At operation 916, apply second lamination layer to exposed first side. The second lamination layer of lamination 1030 may cover the sputtering layer 1020A. The lamination 1030 may be, for example, a dry film or the like. An illustration of an example embodiment after this operation has been performed is in FIG. 10H.

At operation 918, develop second lamination pattern in second lamination layer for traces. A second lamination pattern may be developed in the second lamination layer 1030 by removing one or more portions of the lamination 1030 of the second lamination layer. For example, one or more portions of the lamination 1030 may be removed to provide a pattern for traces, vias, and/or electrical connections to the BTB die, particularly wafer 110A. The second lamination layer may have the pattern developed by, for example, laser direct imaging (LDI) or the like. An illustration of an example embodiment after this operation has been performed is in FIG. 10I.

At operation 920, plate exposed first side. Metal plating on the exposed first side may generate vias and/or traces. The metal plating may, for example, be copper. An illustration of an example embodiment after this operation has been performed is in FIG. 10J.

At operation 922, apply third lamination layer to exposed first side. The third lamination layer of lamination 1030 may cover prior lamination layer(s) and/or metal plating of vias and/or traces. The lamination 1030 may be, for example, a dry film or the like. An illustration of an example embodiment after this operation has been performed is in FIG. 10K.

At operation 924, develop third lamination pattern in third lamination layer for studs. A third lamination pattern may be developed similar to the development of the second lamination pattern. For example, the third lamination pattern may have one or more portions of the lamination 1030 removed to provide a pattern for studs and/or electrical connections to the Si blocks 242 for a heat sink. An illustration of an example embodiment after this operation has been performed is in FIG. 10L.

At operation 926, plate exposed first side. Metal plating on the exposed first side may generate studs 282 (e.g., 282A, 282B) that electrically coupled a heat sink and Si blocks 242 (e.g., 242A, 242B). The metal plating may, for example, be copper. An illustration of an example embodiment after this operation has been performed is in FIG. 10M.

At operation 928, strip lamination from exposed first side. Stripping the lamination 1030 may remove the lamination 1030. For example, the lamination stripping may remove dry film lamination. An illustration of an example embodiment after this operation has been performed is in FIG. 10N.

At operation 930, etch to remove sputtering from exposed second side. The etch may remove the sputtering layer 1020A, such as a Ti/Cu sputtering layer or the like. An illustration of an example embodiment after this operation has been performed is in FIG. 10O.

At operation 932, apply third molding to exposed first side. The third molding may be applied to encase the first side, including studs (e.g., 282A, 282B) and/or electrical traces (e.g., 1032A, 1032B). The third molding may (or may not) be the same as the first molding 120 and/or second molding. An illustration of an example embodiment after this operation has been performed is in FIG. 10P.

At operation 934, back grind molding on exposed first side. Back grinding the exposed first side may remove molding 120 to expose studs (e.g., 282A, 282B) while leaving traces 1032A, 1032B encased in molding 120. An illustration of an example embodiment after this operation has been performed is in FIG. 10Q.

At operation 936, sputter exposed second side. The sputtering may be with a sputtering material, such as Ti/Cu or the like. The sputtering may create a second sputtering layer 1020B. An illustration of an example embodiment after this operation has been performed is in FIG. 10R.

At operation 938, apply fourth lamination layer to exposed first side. The third lamination layer of lamination 1030 may cover the second sputtering layer 1020B. The lamination 1030 may be, for example, a dry film or the like. An illustration of an example embodiment after this operation has been performed is in FIG. 10S.

At operation 940, develop fourth lamination pattern in fourth lamination layer for heat sink. A fourth lamination pattern may be developed similar to the development of the second lamination pattern. For example, the fourth lamination pattern may have one or more portions of the lamination 1030 removed to provide a pattern for a heat sink and/or electrical connections to one or more the studs (e.g., 282A, 282B). An illustration of an example embodiment after this operation has been performed is in FIG. 10T.

At operation 942, plate exposed first side. Metal plating on the exposed first side may generate a heat sink 160 that is electrically coupled studs 282 (e.g., 282A, 282B). An illustration of an example embodiment after this operation has been performed is in FIG. 10U.

At operation 944, strip lamination from exposed first side. Stripping the lamination 1030 may remove the lamination 1030. For example, the lamination stripping may remove dry film lamination. An illustration of an example embodiment after this operation has been performed is in FIG. 10V.

At operation 946, etch to remove sputtering from exposed first side. The etch may remove the sputtering layer 1020AB such as a Ti/Cu sputtering layer or the like. An illustration of an example embodiment after this operation has been performed is in FIG. 10W.

At operation 948, apply fourth molding. The fourth molding may be applied to encase the first side, including the heat sink 160. The fourth molding may (or may not) be the same material as the first molding 120, second molding, and/or third molding. An illustration of an example embodiment after this operation has been performed is in FIG. 10X.

At operation 950, back grind exposed first side. Back grinding the exposed first side may remove molding 120 to expose the heat sink 160 while the remainder of the first side of the semiconductor package encased in molding 120. An illustration of an example embodiment after this operation has been performed is in FIG. 10Y.

FIG. 11 illustrates an example flowchart of operations for finishing semiconductor package(s) in accordance with one or more embodiments of the present disclosure.

At operation 1102, release the panel. The panel may be released from the carrier 1010.

At operation 1104, apply panel finishing. Panel finishing may include applying one or more plating layers to the terminals on the first side and second side of the panel to prevent oxidation of copper terminals. For example, panel finishing may include an electroless nickel immersion gold (ENIG) plating to the terminals of each semiconductor package on the panel.

At operation 1106, perform package singulation. Package singulation may include cutting or dicing the panel into individual semiconductor packages.

Various operations have been described herein, and it will be appreciated that one or more of the operations may be iterated and/or repeated. For example, multiple operations described herein may be iterated to form additional traces in different layers that may electrically couple to additional Si blocks at various positions in the semiconductor package.

### CONCLUSION

While this specification contains many specific embodiments and implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are illustrated in the drawings in a particular order, this should not be understood as requiring that such operations be performed in the particular order shown or in sequential order, or that all illustrated operations be performed, to achieve desirable results. In certain circumstances, operations in alternative ordering may be advantageous. In some cases, the actions recited in the claims may be performed in a different order and still achieve desirable results. Thus, while particular embodiments of the subject matter have been described, other embodiments are within the scope of the following claims.

While this detailed description has set forth some embodiments of the present invention, the appended claims cover other embodiments of the present invention which differ from the described embodiments according to various modifications and improvements.

Within the appended claims, unless the specific term “means for” or “step for” is used within a given claim, it is not intended that the claim be interpreted under 35 U.S.C. § 112, paragraph 6.

1. A semiconductor package comprising:
a first side of the semiconductor package and a second side of the semiconductor package, wherein the second side of the semiconductor package includes a plurality of terminals;
a back-to-back (BTB) die comprised of a first die electrically coupled to a second die;
the first die electrically coupled to a first portion of the plurality of terminals through a first plurality of electrical traces and a plurality of Si blocks;
the second die electrically coupled to a second portion of the plurality of terminals through a second plurality of electrical traces;
wherein the BTB die is configured to cease functioning if an electrical connection to one of the plurality of terminals is broken.

2. The semiconductor package of claim 1 further comprising a heat sink on the first side of the semiconductor package.

3. The semiconductor package of claim 2, wherein the heat sink is coupled to one or more terminals on the second side of the semiconductor package by one or more Si blocks.

4. The semiconductor package of claim 1, wherein the first die is electrically coupled to the first plurality of traces with a plurality of vias through a first lamination layer.

5. The semiconductor package of claim 4, wherein the first lamination layer is comprised of ABF.

6. The semiconductor package of claim 1, wherein at least one of the plurality of Si blocks is positioned on at least a first lateral side of the BTB die and at least a second of the plurality of Si blocks is positioned on at least a second lateral side of the BTB die.

7. The semiconductor package of claim 1, wherein each lateral side of the BTB die has at least one of the plurality of Si blocks are positioned on the respective lateral side.

8. The semiconductor package of claim 1, wherein a first Si block of the plurality of Si blocks is a different height than at least a second Si block of the plurality of Si blocks.

9. The semiconductor package of claim 1, wherein the plurality of electrical traces are in a fan-out pattern.

10. The semiconductor package of claim 1, wherein the semiconductor package is a first semiconductor package in a plurality of semiconductor packages in a panel.

11. A method of manufacturing a semiconductor package comprising:
preparing a back-to-back (BTB) die comprising of a first die electrically coupled to a second die;
forming a first side of the semiconductor package and a second side of the semiconductor package including electrically coupling a plurality of Si blocks to the first die via a plurality of traces and electrically coupling a plurality of terminals on the second side of the semiconductor package to the second die;
wherein the BTB die is configured to cease functioning if an electrical connection to one of the plurality of terminals is broken.

12. The method of manufacturing of claim 11, wherein forming a first side of the semiconductor package and a second side of the semiconductor package further includes forming a heat sink on the first side of the semiconductor package.

13. The method of manufacturing of claim 12, wherein forming a first side of the semiconductor package and a second side of the semiconductor package further includes forming the heat sink on the first side of the semiconductor package to be electrically coupled to one or more of the plurality of Si blocks.

14. The method of manufacturing of claim 11, wherein forming a first side of the semiconductor package and a second side of the semiconductor package further includes electrically coupling the plurality of traces to the first die with a plurality of vias through a first lamination layer.

15. The method of manufacturing of claim 14, wherein the first lamination layer is comprised of ABF.

16. The method of manufacturing of claim 11, wherein at least one of the plurality of Si blocks is positioned on at least a first lateral side of the BTB die and at least a second of the plurality of Si blocks is positioned on at least a second lateral side of the BTB die.

17. The method of manufacturing of claim 11, wherein each lateral side of the BTB die has at least one of the plurality of Si blocks are positioned on the respective lateral side.

18. The method of manufacturing of claim 11, wherein a first Si block of the plurality of Si blocks is a different height than at least a second Si block of the plurality of Si blocks.

19. The method of manufacturing of claim 11, wherein the plurality of electrical traces are in a fan-out pattern.

20. The method of manufacturing of claim 11, wherein the semiconductor package is a first semiconductor package in a plurality of semiconductor packages in a panel.
